(19) United States
(12) Patent Application Publication
(10) Pub. No.: US 2016/0173055 A1
(43) Pub. Date: Jun. 16, 2016

(54) IMPEDANCE MATCHING IN A TRANSMISSION LINE

(71) Applicant: INTEL CORPORATION, Santa Clara, CA (US)

(72) Inventors: Michael W. Leddige, Beaverton, OR (US); Wei Jern Tan, Georgetown (MY); Chee Kit Chew, Georgetown (MY); Natasya Athirah Abdul Khalid, Bayan Lepas (MY); Howard L. Heck, Hillsboro, OR (US)

(73) Assignee: INTEL CORPORATION, Santa Clara, CA (US)

(21) Appl. No.: 14/569,981

(22) Filed: Dec. 15, 2014

(51) Int. Cl. H03H 7/38; H01P 3/08

(52) U.S. Cl. CPC H03H 7/38; H01P 3/081

(57) ABSTRACT

Techniques for impedance matching are described herein. The techniques include an apparatus for impedance matching including a trace section having a load impedance. The trace section comprises characteristics generating an impedance match between a main channel impedance and the load impedance.

### TECHNICAL FIELD

This disclosure relates generally to impedance matching. Specifically, this disclosure relates to impedance matching on a transmission line.

### BACKGROUND

Computing devices are increasingly becoming more standardized such that a computing device may communicate to a peripheral device using various protocols over the same physical connector. For example, Universal Serial Bus (USB) Type “C” connector may enables high-speed differential pins on the cable to be multi-purposed for guest protocols such as Display Port Protocols, High Definition Multimedia Interface (HDMI), and the like. Such universal approaches may enable multiple devices to be operated from a single connector. For example, with one platform connector a user may connect a power charger, a USB device, a monitor, and the like. In some cases, transmission lines enabling guest protocols may include additional components, such as multiplexers, increase capacitance and therefore decrease a load impedance causing a mismatch between a transmission impedance of the transmission line and the load impedance.

### BRIEF DESCRIPTION OF THE DRAWINGS

FIG. 1 illustrates a block diagram computing device having a transmission line and components adding a load capacitance on the transmission line;

FIG. 2A is a diagram illustrating a transmission line having a trace section to compensate for added load capacitance;

FIG. 2B is a diagram illustrating a circuit model for a transmission line having a trace section;

FIG. 3 is a block diagram illustrating a topology for a Universal Serial Bus (USB) Connector and trace sections near the USB connector;

FIG. 4 is table illustrating improvements in eye margins as a result of the trace section

FIG. 5 is a diagram illustrating a topology for a USB connector and trace sections near components for a transmission line;

FIG. 6 is a table illustrating improvements in eye margins as a result of the trace sections; and

FIG. 7 is a block diagram illustrating a method for impedance matching on a transmission line.

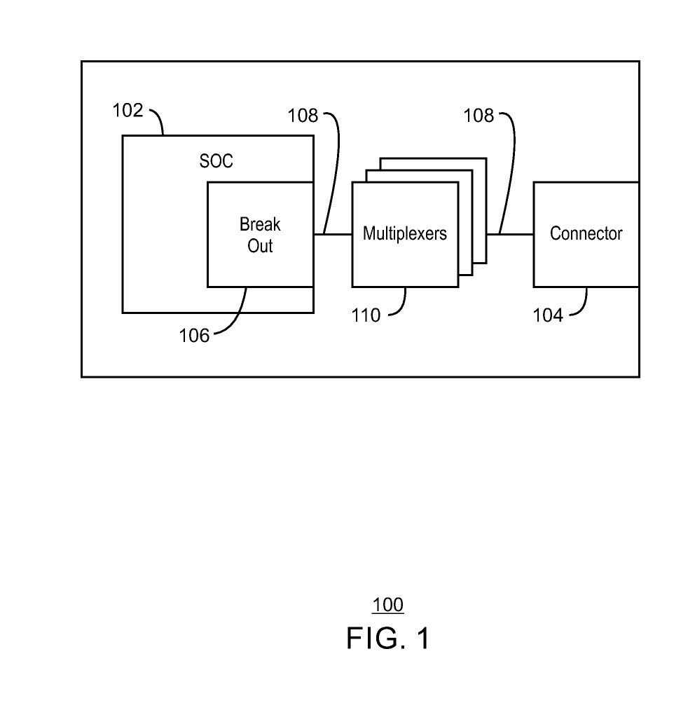

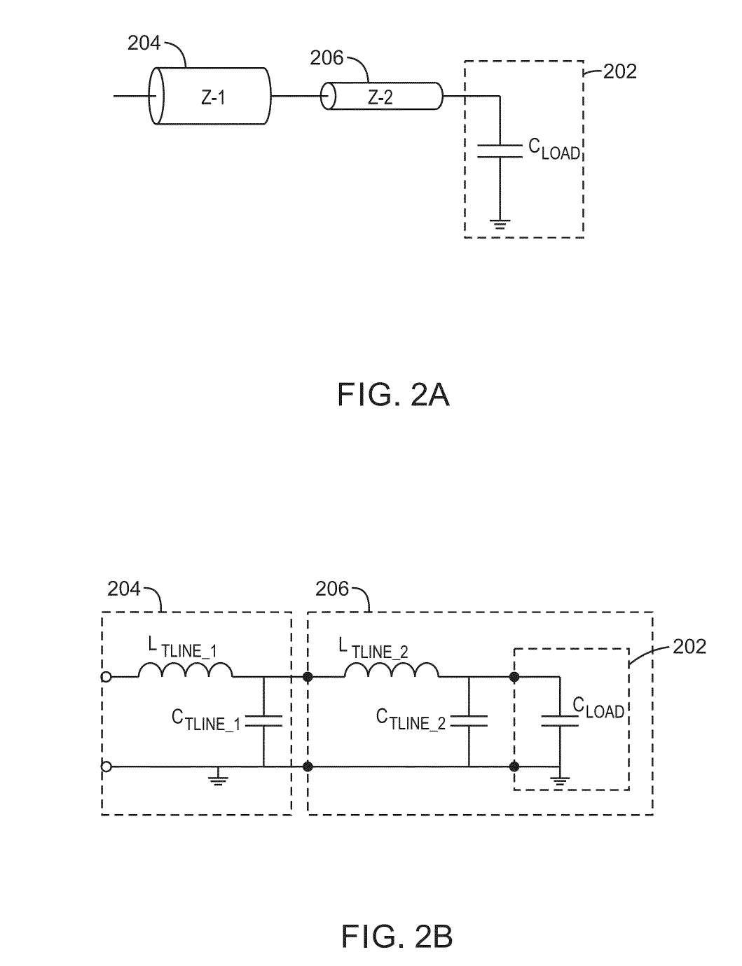

In some cases, the same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

The techniques described herein relate to impedance matching. As discussed above, universal connectors may enable a smoother user experience as one connector may be used to for multiple purposes and to be configure to propagate a variety of protocols. To support a platform level solution of this sort, discrete multiplexers (MUXes) may be required. However, these MUXes introduce significant load onto a transmission line. In some cases, board routing length from a System on Chine (SOC) to a connector, such as the USB Type C connector, may be limited.

Further, in the USB Type C connector may be flippable. For example, a USB Type C plug may be received at a USB Type C connector in either a right side up orientation or a right side down orientation. In this case, a dual stub connection may be used to enable flippability at the USB Type C connector. The stub connections may introduce a reflection in the transmission of signals and may reduce the maximum allowable line length. When combined with a MUX component, such as a Battery Charging 1.2 Compliance Plane, Revision 1.0, Oct. 12, 2011 (BC 1.2) charging component, line length may be further limited due to a capacitive loading of the charging component.

The techniques described herein include impedance matching through trace shape modification. Impedance matching through trace shape modification may increase the maximum allowable routed length of a transmission line. Further, impedance matching may increase throughput, may increase eye diagram margins, and the like. The impedance matching may be enabled, in some cases, without any additional components added.

For example, USB channel impedance may be approximately 85 ohms. The introduction of discrete loads as a result of MUXes being added also increases capacitance, lowers the channel impedance, and may reduce eye margins beyond a compliance point. As discussed in more detail below, the techniques described herein include adjusting dimensions of a section of a printed circuit board (PCB) such that higher impedance is introduced to a transmission line. The higher impedance trace is to connect to connectors, MUXes, charging components, and the like, to counteract the capacitive loading resulting from the introduction of the discrete loads and reflections discussed above.

Although implementations discussed above include impedance matching for a USB connector and transmission line, other connectors and/or transmission lines may be considered. For example, other transmission lines having stubs or components affecting the impedance of a main channel may be benefit from the techniques described herein. Further, a main channel impedance is discussed in detail below. In aspects, a main channel impedance is a characteristic impedance of a transmission line as a whole. In some cases, a main channel impedance is a characteristic impedance of a transmission line as a whole without consideration of any impedance effect due to stubs, impedance varying components, or the line.

Further, an impedance match, as referred to herein, is a matching of an impedance of a trace section to a reference impedance, such as the main channel impedance. An impedance match need not be an exact match but may be based on a range of impedance values. In some cases, determining whether an impedance match has been achieved may be based on a desired signal strength, signal eye height margin, and the like, rather than exact impedance value matching.

FIG. 1 illustrates a block diagram computing device having a transmission line and components adding a load capacitance on the transmission line. The computing device component 100 may be a printed circuit board (PCB). Therefore, the computing device component 100 may be referred to herein as PCB 100. PCB 100 may be configured to connect a system on chip (SoC) 102 to a connector 104. The SoC 102 may have a breakout section 106 to be connected to the connector 104 through a transmission line 108 having a main channel impedance. As discussed above, in some cases, MUXes 110 may be added to the transmission line. The MUXes 110 may increase a load capacitance causing a decrease in load impedance and a mismatch between the load impedance and the main channel impedance.

For example, the main channel impedance may be 85 ohms. One or more of the MUXes 110 may introduce an increased capacitance, and therefore a decreased load-based impedance below 85 ohms. In the techniques described herein, a trace section may be introduced between the transmission line 108 having a main channel impedance and a component, such as a MUX 110, having a lower load-based impedance. The trace section may have a higher impedance to compensate for the lower load-based impedance introduced by the component.

FIG. 2A is a diagram illustrating a transmission line having a trace section to compensate for added load capacitance. As discussed above, a component, such as a MUX 110 of FIG. 1, added to a transmission line may increase capacitance and decrease an impedance load on the transmission line. In FIG. 2, a load capacitance is added by a component, such as a MUX 110 of FIG. 1, as indicated at 202. A main channel impedance, Z_1, is indicated at 204, and an impedance of the trace section, Z_2, is indicated at 206.

In impedance matching, the main channel impedance 204 and the trace section impedance 206 may be set equal to each other. As discussed in more detail below, by setting each of 204 and 206 equal to each other, a length may be calculated for the trace section to compensate for added capacitance of a MUX 110.

FIG. 2B is a diagram illustrating a circuit model for a transmission line having a trace section. The circuit model illustrated in FIG. 2B is an equivalent circuit model for the transmission line diagram of FIG. 2A. For example, the main channel impedance Z_1 is indicated by the dashed box 204 and the trace section impedance Z_2 is indicated by the dashed box 206. As indicated in FIG. 2B, the trace section impedance 206 comprises a factor of the capacitive load of the added component 202. Therefore, the trace section impedance 206 may be referred to herein as a load impedance 206, or Z_2.

In order to match the main channel impedance Z_1 204 and the load impedance Z_2 206, the respective impedances may be set equal to each other as indicated in Equation 1 and Equation 2 below:

$$\begin{matrix}If \\ {Z}_{1} = \sqrt{\frac{{L}_{TLINE\_ 1}}{{C}_{TLINE\_ 1}}} \\ and \\ {Z}_{2} = \sqrt{\frac{{L}_{TLINE\_ 2}}{{C}_{TLINE\_ 2} + {C}_{LOAD}}} & Eq . 1 \\ \sqrt{\frac{{L}_{TLINE\_ 1}}{{C}_{TLINE\_ 1}}} = \sqrt{\frac{{L}_{TLINE\_ 2}}{{C}_{TLINE\_ 2} + {C}_{LOAD}}} & Eq . 2\end{matrix}$$

In Eq. 1, L_Tline_1 is the distributed inductance of the main channel, and C_Tline_1 is the distributed capacitance of the main channel. Further, L_Tline_2 is the inductance of the trace section, C_Tline_2 is the distributed capacitance of the trace section, and C_Load is the capacitance from the added component. The main channel impedance Z_1 204 is set to equal to the load impedance Z_2 206 in Eq. 2. Further, inductance and capacitance are functions of length. As illustrated in Equations 3-5 below, if the impedance of the main channel Z_1 204 is known, a length for the trace section can be derived:

$$\begin{matrix}{Z}_{0 \_ 1} = \sqrt{\frac{{L}_{TLINE\_ 2} \times Length}{{C}_{TLINE\_ 2} \times Length + {C}_{LOAD}}} & Eq . 3 \\ {C}_{TLINE\_ 2} \times Length + {C}_{LOAD} = \frac{{L}_{TLINE\_ 2} \times Length}{{Z}_{0 \_ 1}^{2}} & Eq . 4 \\ Length = \frac{{C}_{LOAD}}{\frac{{L}_{TLINE\_ 2}}{{Z}_{0 \_ 1}^{2}} - {C}_{TLINE\_ 2}} & Eq . 5\end{matrix}$$

For example, assuming a main channel impedance is 85 ohms and a 1 power factor (pF) load, and a 100 ohm micro strip is used as the trace section for impedance matching. In this scenario, inductance “L_Tline_2” is 15 nanohenries (nH) per inch, and the capacitance C_Tline_2 is 1.5 picohenries (pH) per inch. Using Eq. 5 above, the trace segment has a length of 1.75 inches of 100 ohm routing to match the main channel impedance of 85 ohms.

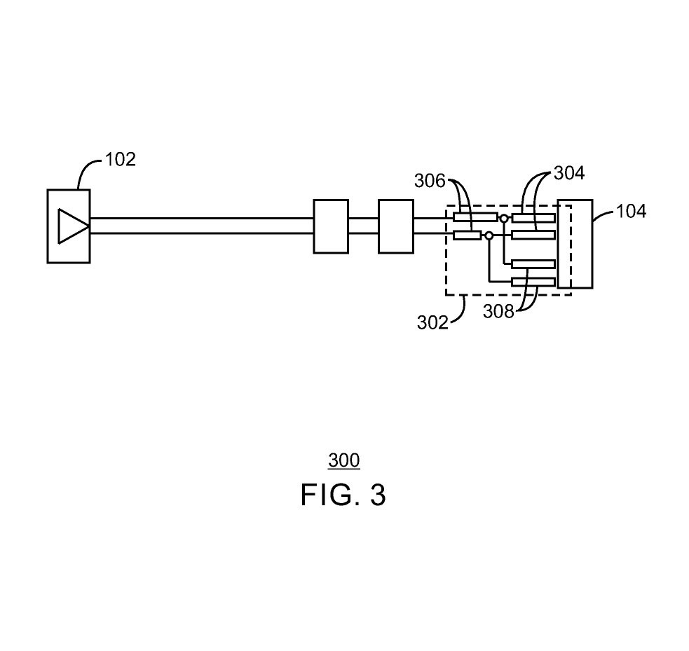

FIG. 3 is a block diagram illustrating a topology for a Universal Serial Bus (USB) Connector and trace sections near the USB connector. As discussed above, components as well as stubs may affect an impedance matching for a transmission line 300. In FIG. 3, trace segments are used in an end-of-line implementation involving dual stubs of a connector, such as the connector 104. In the example of FIG. 3, the connector 104 may be an USB Type C connector wherein dual stubs are used to implement a flippability feature of the connector 104. To reduce an effect that stub reflection may have on the transmission line 300, trace segments, indicated at dashed box 302, may be implemented having relatively high impedance when compared to the transmission line 300.

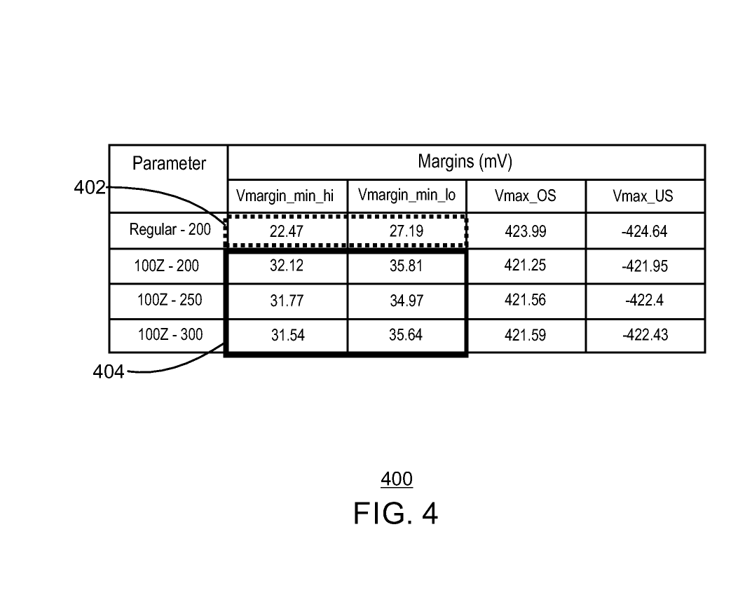

For example, the trace segments 304, 306, and 308 may be traces having 100 ohm impedance that is intentionally higher than an 85 ohm impedance of the transmission line 300. Without trace segments 304, 306, and 308, a total length of the transmission line 300 from connector 104 to an SoC, such as the SoC 102 of FIG. 1, may be limited to about 9 inches. However, with the embodiments described herein, an 11 inch transmission line 300 was used with improved eye diagram margins, as discussed in more detail below in reference to FIG. 4. Further, even effects associated with increases in stub lengths may still be compensated by the impedance matching via the trace sections generally indicated at 304.

Examples of trace segment dimensions may include a trace segment that is 3.5 millimeters wide, with a spacing of 8 millimeters between the pair, and 20 millimeter spacing between other pairs. In this example, the impedance of the trace section 304 is 100 ohms and the stub length is 250 millimeters.

FIG. 4 is table illustrating improvements in eye margins as a result of the trace section. As illustrated in table 400, improved eye diagram margins may be achieved by implementing the techniques described herein. For example, at 402, maximum margins and minimum margins are 22.5 volts and 27.2 volts, respectively, without the impedance matching described herein. However, as indicated at 404, voltage margins improved even with a higher stub length parameter.

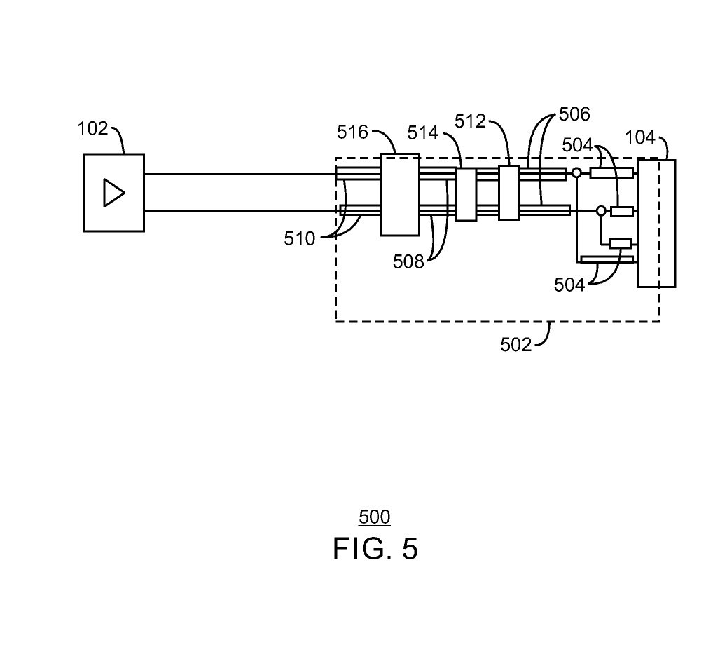

FIG. 5 is a diagram illustrating a topology for a USB connector and trace sections near components for a transmission line. Similar to FIG. 3, a connector 104 may be connected to an SoC through a transmission line 500. Trace segments having a relatively higher impedance than the transmission line 500 may be introduced, as generally indicated by the dashed box 502. In this scenario, traces 504 lead out of the connector 104. Further, traces 506, 508, and 510 lean into and out of components including an electrostatic protection diode 512, a common choke mode 514, and a BC 1.2 charging component 516. Each of the components 504, 506, 508 may introduce a load capacitance resulting in decreased load impedance in comparison to the main channel impedance as discussed above in regard to FIG. 2.

The use of high impedance trace sections in FIG. 5 improved received signal quality and allow for a component having a higher load and/or a potentially longer channel length. For example, without the trace sections 504, 506, 508, and 510, the length of the transmission line 500 may be limited to 6 inches. However, the trace sections 504, 506, 508, 510 used to match the main channel impedance of the transmission line 500 enable a length of loner than 6 inches. In general the higher impedance is obtained by narrowing the width of a given trace segment. Therefore, no additional parts may be required.

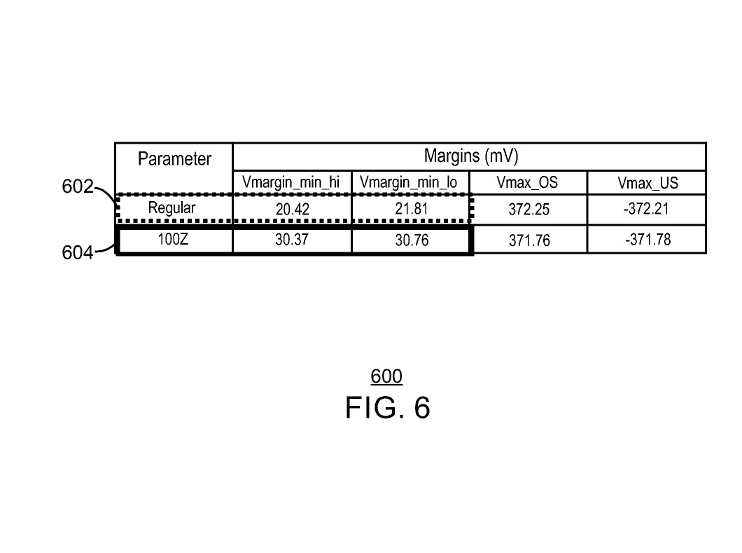

FIG. 6 is a table illustrating improvements in eye margins as a result of the trace sections. As discussed above in regard to FIG. 5, the use of higher impedance trace sections may result in improved signal quality. The table 600 illustrates that without trace sections, the maximum margins and minimum margins are 20.42 volts and 21.81 volts, respectively, as indicated at 602. In contrast, with the trace sections, the maximum margins and minimum margins are increased, as indicated at 604.

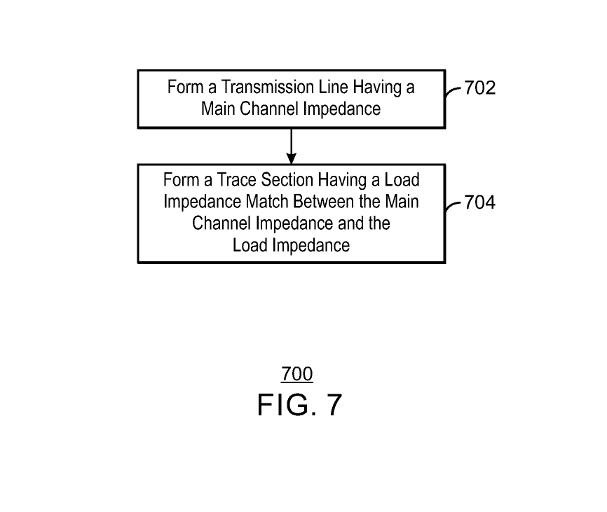

FIG. 7 is a block diagram illustrating a method for impedance matching on a transmission line. At block 702, a transmission line is formed having a main channel impedance. At block 704, a trace section is formed having a load impedance having an impedance match between the main channel impedance and the load impedance.

In embodiments, the match between the load impedance and the main channel impedance is based in part on characteristics of the trace section. For example, the impedance may be defined as a function of the dimensions of the trace section such as the width and length of the trace section. As discussed above, the length of the trace section may be determined by defining a relationship between the main channel impedance and the length of the trace section, as well as the capacitance of the trace section, the inductance of the trace section, and the capacitive load of a component being added to the main channel.

In some cases, the main channel impedance is an average impedance for the transmission line as a whole. In some cases, the main channel impedance is an average impedance for the transmission line as a whole without the added capacitance of any added component or trace stub.

The characteristics of the trace section may include an inductance per unit length of the trace section. The characteristics of the trace section may further include a capacitance per unit length of the race second. In other words, the transmission impedance of the trace section is based on the dimensions of the trace section, while the load impedance of the trace section may be based on the transmission impedance plus a load impedance due as a result of an added component such as a charging MUX.

Example 1 includes an apparatus for impedance matching. In this example, the apparatus includes a transmission line having a main channel impedance, and a trace section having a load impedance. The trace section includes characteristics generating an impedance match between the main channel impedance and the load impedance.

Example 2 includes a method for impedance matching. In this example, the method includes forming a transmission line having a main channel impedance, and forming a trace section having a load impedance. The trace section includes characteristics generating an impedance match between the main channel impedance and the load impedance. In this example, the load impedance of the trace section may be based on a transmission impedance of the trace section and an added capacitance of a component coupled to the trace section. Further, the main channel impedance may be an average impedance for the transmission line as a whole.

Example 3 includes a system for impedance matching. In this example, the system includes a transmission line having a main channel impedance, a component having a capacitance, and a trace section having a load impedance. The trace section includes characteristics generating an impedance match between the main channel impedance and the load impedance. In this example, the load impedance of the trace section may be based on a transmission impedance of the trace section and the capacitance of the component coupled to the trace section.

Example 4 includes an apparatus for impedance matching. In this example, the apparatus includes a transmission line having a main channel impedance, and a trace section having a load impedance. The trace section includes a means for generating an impedance match between the main channel impedance and the load impedance. In this example, the means for generating an impedance match between the main channel impedance and the load impedance may include characteristics of the trace section. Characteristics of the trace section may include a width of the trace section, a length of the trace section, an inductance per unit length of the trace section, a capacitance per unit length of the trace section, and the like.

Example 5 includes a method for impedance matching. In this example, the method includes forming a transmission line having a main channel impedance, and forming a trace section having a load impedance. The trace section includes a means for generating an impedance match between the main channel impedance and the load impedance.

In Example 5, the means for generating an impedance match between the main channel impedance and the load impedance may include characteristics of the trace section. Characteristics of the trace section may include a width of the trace section, a length of the trace section, an inductance per unit length of the trace section, a capacitance per unit length of the trace section, and the like. Further, in Example 5, the transmission means may include a transmission line, such as a USB signal line.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams and/or state diagrams may have been used herein to describe embodiments, the techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. An apparatus for impedance matching, comprising:
a trace section having a load impedance, wherein the trace section comprises characteristics generating an impedance match between a main channel impedance and the load impedance.

2. The apparatus for impedance matching of claim 1, wherein the main channel impedance is an average impedance for a transmission line as a whole.

3. The apparatus for impedance matching of claim 1, wherein the load impedance of the trace section is based on a transmission impedance of the trace section and an added capacitance of a component coupled to the trace section.

4. The apparatus for impedance matching of claim 3, wherein the main channel impedance is an average impedance for a transmission line as a whole without the added capacitance of the component.

5. The apparatus for impedance matching of claim 3, wherein the characteristics of the trace section comprise an inductance per unit of length of the trace section and a capacitance per unit length of the trace section.

6. The apparatus for impedance matching of claim 5, wherein the transmission impedance of the trace section is based on the dimensions of the trace section.

7. The apparatus for impedance matching of claim 3, wherein the component comprises:
a multiplexer;
a via stub;
or any combination thereof.

8. The apparatus for impedance matching of claim 7, wherein the via stub is a component of a connector to receive a flippable plug.

9. The apparatus for impedance matching of claim 1, wherein the trace section characteristics comprise a thinner width than other trace sections of a main channel.

10. The apparatus for impedance matching of claim 1, wherein the impedance match is generated when the load impedance is within a range of the main channel impedance.

11. A method for impedance matching, the method comprising:
forming a transmission line having a main channel impedance; and
forming a trace section having a load impedance, wherein the trace section comprises characteristics generating an impedance match between the main channel impedance and the load impedance.

12. The method for impedance matching of claim 11, wherein the main channel impedance is an average impedance for the transmission line as a whole.

13. The method for impedance matching of claim 11, wherein the load impedance of the trace section is based on a transmission impedance of the trace section and an added capacitance of a component coupled to the trace section.

14. The method for impedance matching of claim 13, wherein the main channel impedance is an average impedance for the transmission line as a whole without the added capacitance of the component.

15. The method for impedance matching of claim 13, wherein the characteristics of the trace section comprise an inductance per unit of length of the trace section and a capacitance per unit length of the trace section.

16. The method for impedance matching of claim 15, wherein the transmission impedance of the trace section is based on the dimensions of the trace section.

17. The method for impedance matching of claim 13, wherein the component comprises:
a multiplexer;
a via stub;
or any combination thereof.

18. The method for impedance matching of claim 17, wherein the via stub is a component of a connector to receive a flippable plug.

19. The method for impedance matching of claim 11, wherein the trace section is comprises a thinner width than other trace sections of the transmission line.

20. The method for impedance matching of claim 11, wherein the impedance match is generated when the load impedance is within a range of the main channel impedance.

21. A system for impedance matching, the system comprising:
a transmission line having a main channel impedance;
a component having a capacitance; and
a trace section having a load impedance based, in part, on the capacitance of the component, wherein the trace section comprises characteristics generating an impedance match between the main channel impedance and the load impedance.

22. The system for impedance matching of claim 21, wherein the load impedance of the trace section is based on a transmission impedance of the trace section and the capacitance of the component, wherein the component comprises:
a multiplexer;
a via stub;
or any combination thereof.

23. The system for impedance matching of claim 22, wherein the main channel impedance is an average impedance for the transmission line as a whole without the added capacitance of the component.

24. The system for impedance matching of claim 22, wherein the characteristics of the trace section comprise an inductance per unit of length of the trace section and a capacitance per unit length of the trace section.

25. The system for impedance matching of claim 21, wherein the trace section is comprises a thinner width than other trace sections of the transmission line.
